(19) United States
(12) Patent Application Publication
(10) Pub. No.: US 2024/0429112 A1
(43) Pub. Date: Dec. 26, 2024

(54) COMPOSITION, AND PHOTOELECTRIC CONVERSION ELEMENT MANUFACTURING METHOD

(71) Applicant: Panasonic Holdings Corporation, Osaka (JP)

(72) Inventor: Takayuki YAMAMOTO, Osaka (JP)

(73) Assignee: Panasonic Holdings Corporation, Osaka (JP)

(21) Appl. No.: 18/824,420

(22) Filed: Sep. 4, 2024

Related U.S. Application Data
(63) Continuation of application No. PCT/JP2023/000228, filed on Jan. 6, 2023.

(30) Foreign Application Priority Data
Mar. 8, 2022 (JP) 2022-035605

(51) Int. Cl. H01L 23/29; H10K 50/16; H10K 85/50

(52) U.S. Cl. CPC H01L 23/291; H10K 50/16; H10K 85/50

(57) ABSTRACT

A composition according to the present disclosure includes: a metal oxide; a metal oxide precursor; and a solvent. The metal oxide precursor includes at least one selected from the group consisting of a metal acetate, a metal carbonate, a metal hydroxide, a metal alkoxide, and a metal acetylacetonate complex, where the metal oxide and the metal oxide precursor include different metal elements. A method for manufacturing a photoelectric conversion element of the present disclosure includes: a first electrode; a second electrode; and a metal-oxide-containing layer, and the method includes forming the metal-oxide-containing layer by firing the composition of the present disclosure. A photoelectric conversion element obtained by the manufacturing method according to the present disclosure includes, for example, a substrate, a first electrode, an electron transport layer, a photoelectric conversion layer, a hole transport layer, and a second electrode in this order.

This application is a continuation of PCT/JP2023/000228 filed on Jan. 6, 2023, which claims foreign priority of Japanese Patent Application No. 2022-035605 filed on Mar. 8, 2022, the entire contents of both of which are incorporated herein by reference.

### BACKGROUND OF THE INVENTION

### 1. Field of the Invention

The present disclosure relates to a composition and a photoelectric conversion element manufacturing method.

### 2. Description of Related Art

In recent years, research and development of organic thin-film solar cells and perovskite solar cells have been progressing, and these novel solar cells are regarded as replacing the existing silicon-type solar cells. A perovskite solar cell uses a perovskite-type crystal represented by ABX₃ (here, A is a monovalent cation, B is a divalent cation, and X is a monovalent anion) or a similar structure (hereafter referred to as “perovskite compound”) as the photoelectric conversion material.

A perovskite solar cell including a laminate formed of a SnO₂ layer and a MgO layer as electron transport layers for the purpose of extending the life of the solar cell is disclosed in “Highly efficient perovskite solar cells for light harvesting under indoor illumination via solution processed SnO2/MgO composite electron transport layers”, Nano Energy, 49, 290-299 (2018). [DOI: 10.1016/j.nanoen.2018.04.027].

### SUMMARY OF THE INVENTION

The present disclosure aims to provide a composition suitable for forming a structure including a metal oxide.

A composition of the present disclosure includes:
a metal oxide;
a metal oxide precursor; and
a solvent, wherein
the metal oxide precursor includes at least one selected from the group consisting of a metal acetate, a metal carbonate, a metal hydroxide, a metal alkoxide, and a metal acetylacetonate complex, and
the metal oxide and the metal oxide precursor include different metal elements.

The present disclosure provides a composition suitable for forming a structure including a metal oxide.

### BRIEF DESCRIPTION OF THE DRAWINGS

FIG. 1 shows a cross-sectional view of a photoelectric conversion element 100 obtainable by a manufacturing method according to a second embodiment.

FIG. 2 shows a cross-sectional view of a photoelectric conversion element 200, which is a variation of a photoelectric conversion element obtainable by the manufacturing method according to the second embodiment.

### DETAILED DESCRIPTION

### <Findings Underlying the Present Disclosure>

As described in the literature of “Qingfeng Dong et al., Science, 2015, 347, 6225, 967-970”, a perovskite solar cell can generate electricity efficiently over a thickness of several hundred nanometers due to its high light absorption coefficient and a long diffusion length, both of which are the distinguishing physical properties of perovskite compounds. Further features of the perovskite solar cell include: fewer materials are used therefor in comparison with existing silicon solar cells; the formation process does not require high temperatures; and the solar cell can be formed by a coating.

When considering practical use of a perovskite solar cell, photoelectric conversion efficiency and lifetime are important indicators. Accelerated thermal testing has been known as a common method to evaluate the lifetime. This is a test to evaluate the change over time in photoelectric conversion efficiency when a perovskite solar cell is held at a high temperature.

Modification of the electron transport layer has been reported as one method to achieve high efficiency and long life of perovskite solar cells. By modifying the surface of the electron transport layer with a material that has a larger energy bandgap than the material of the electron transport layer, a hole-electron recombination that will occur at the interface between the electron transport layer and the photoelectric conversion layer can be suppressed. This can improve the photoelectric conversion efficiency. As an example, Non Patent Literature 1 reports a perovskite solar cell including a SnO₂ layer/MgO layer laminate as the electron transport layer, where the surface of the SnO₂ layer is modified with MgO.

Regarding the method for modifying an electron transport layer, the aforementioned Non Patent Literature 1 refers to a method of forming a laminate from two kinds of materials in two separate steps. This method is complicated and thus, it may increase manufacturing cost. For this reason, a process of forming a mixture of two kinds of materials in a single step may be employed to facilitate the manufacturing steps, thereby decreasing the manufacturing cost.

Considering these findings, the present inventor searched for a composition suitable for forming a structure including a metal oxide. The inventor has also discovered that a photoelectric conversion element including an electron transport layer formed using this composition has an improved photoelectric conversion property even if the photoelectric conversion element is held at a high temperature. In the present disclosure, a “photoelectric conversion element” includes an element that converts light into electricity and an element that converts electricity into light.

The term “perovskite solar cell” in the present Description means a solar cell that includes a perovskite compound as a photoelectric conversion material or light absorption material.

### First Embodiment

Hereinafter, a composition according to a first embodiment will be described.

A composition according to the first embodiment includes:
a metal oxide;
a metal oxide precursor; and
a solvent, wherein
the metal oxide precursor includes at least one selected from the group consisting of a metal acetate, a metal carbonate, a metal hydroxide, a metal alkoxide, and a metal acetylacetonate complex, and
the metal oxide and the metal oxide precursor include different metal elements.

Use of this composition makes it possible to easily produce a layer in which plural kinds of metal oxides are uniformly mixed, which can be used, for example, to manufacture a photoelectric conversion element.

The metal oxide precursor included in the composition according to the first embodiment is soluble in a solvent. Since the metal oxide and the metal oxide precursor include different metal elements, a structure that includes plural kinds of metal oxides and where these metal oxides are uniformly mixed can be formed easily. For example, a layer formed using this composition becomes a layer in which plural kinds of metal oxides are uniformly mixed.

A composition according to the first embodiment composition may consist essentially of a metal oxide, a metal oxide precursor, and a solvent. Here, “consist essentially of a metal oxide, a metal oxide precursor, and a solvent” means that a sum of contents of the metal oxide, the metal oxide precursor and the solvent to the content of the entire composition is 90 mass % or more. The content may be 95 mass % or more, or may be 100 mass %. The composition according to the first embodiment may consist of a metal oxide, a metal oxide precursor and a solvent.

The molar ratio of the metal oxide precursor to the metal oxide included in the composition may be 0.002 or more and 0.667 or less. In a case where the molar ratio is 0.667 or less, when the metal oxide is regarded as spherical particles of the same diameter, a structure that may include the metal oxide as particles in contact with each other in a close-packed state can be formed. If the molar ratio is 0.002 or more, the effect of the metal oxide precursor may easily be exhibited. For example, production of a photoelectric conversion element by using this composition makes it possible to achieve an improved photoelectric conversion property even when the composition is held at a high temperature.

The molar ratio of the metal oxide precursor to the metal oxide included in the composition may be 0.0045 or more and 0.0455 or less.

The respective components of the present disclosure composition will be specified hereinafter.

### (Metal Oxide)

A metal oxide may be a semiconductor.

The metal oxide may be, for example, a semiconductor having a bandgap of 3.0 eV or more so as to allow visible light and infrared light to easily pass through.

Examples of the metal oxide include an oxide of Cd, Zn, In, Pb, Mo, W, Sb, Bi, Cu, Hg, Ti, Ag, Mn, Fe, V, Sn, Zr, Sr, Ga, or Cr.

The metal oxide may include at least one selected from the group consisting of TiO₂ and SnO₂. The metal oxide may include SnO₂.

The metal oxide may be particulate. In a case where the metal oxide is particulate, its average particle diameter may be 100 nm or less. This may decrease the resistance of a layer (e.g., an electron transport layer) formed of the composition according to the first embodiment.

### (Metal Oxide Precursor)

The metal oxide precursor includes one selected from the group consisting of a metal acetate, a metal carbonate, a metal hydroxide, a metal alkoxide, and a metal acetylacetonate complex.

These metal oxide precursors each forms a metal oxide by firing.

The metal oxide precursor may include a metal acetate from the viewpoint of the firing temperature for forming the metal oxide.

Examples of the metal acetate includes acetates of Mg, Al, Zn, Mn, Pb, Ag, Hg, Co, and Cu. The acetate may be a complex salt with a hydroxide. When fired, the metal acetates form metal oxides due to degassing of carbon dioxide or the like. The metal acetate may include at least one selected from the group consisting of magnesium acetate, aluminum acetate, and manganese acetate. The metal acetate may include magnesium acetate from the viewpoint of the firing temperature for forming the metal oxide.

Examples of the metal carbonate include carbonates of Mg, Zn, Fe, Mn, Pb, Ag, Cu, and Co. When fired, the metal carbonates form metal oxides.

Examples of the metal hydroxide include hydroxides of Mg and Al. When fired, the metal hydroxides form metal oxides due to degassing of water.

Examples of the metal alkoxide include alkoxides of Mg, Al, Li, Na, Ta, Zr, Ti, and Nb. The metal alkoxides form metal oxides due to hydrolysis.

Examples of the metal acetylacetonate complex include acetylacetonate complexes of Mg, Al, Li, Ca, Ba, Zn, Zr, Ag, Ti, Mo, Cu, Ni, Co, Fe, Cr, Mn, V, In, and Pb.

When fired, the metal acetylacetonate complexes form metal oxides due to degassing of carbon dioxide or the like.

### (Solvent)

A solvent may be water or an organic solvent.

Examples of the organic solvent include ethanol, methanol, propanol, butanol, acetone, acetonitrile, chloroform, N,N-dimethylformamide, dimethyl sulfoxide, ethyl acetate, hexane, tetrahydrofuran, toluene, and xylene. Alternatively, the organic solvent may be a mixture of a plurality of solvents selected from these examples.

From the viewpoint of dispersibility of metal oxide and solubility of metal oxide precursor, the solvent may include water. The solvent may include water as the main component, or the solvent may consist of water. Here, the main component means a component included in the largest amount by volume.

### Second Embodiment

Hereinafter, in a second embodiment, a method for manufacturing a photoelectric conversion element using the composition according to the first embodiment will be described. The matters described with regard to the first embodiment may be omitted as appropriate.

The manufacturing method according to the second embodiment is a method for manufacturing a photoelectric conversion element including a first electrode, a second electrode, and a metal-oxide-containing layer, and the method includes forming the metal-oxide-containing layer by firing the composition according to the first embodiment.

In the manufacturing method according to the second embodiment, the layer can be formed by coating the composition according to the first embodiment and firing.

This makes it possible to easily manufacture a photoelectric conversion element that has an improved photoelectric conversion property even when being held at a high temperature.

The metal-oxide-containing layer may be disposed between the first electrode and the second electrode.

There is no particular limitation on a photoelectric conversion element manufactured by the manufacturing method according to the second embodiment. Examples of the photoelectric conversion element manufactured by the manufacturing method according to the second embodiment include a solar cell, a light-emitting element, and an optical sensor. An example of photoelectric conversion element manufactured by the manufacturing method according to the second embodiment is a solar cell. The solar cell is, for example, a perovskite solar cell.

In a case where the photoelectric conversion element is a solar cell, a metal-oxide-containing layer in the manufacturing method according to the second embodiment is, for example, an electron transport layer.

Production of the photoelectric conversion element by using the composition according to the first embodiment makes it possible to form, for example, an electron transport layer including a mixture of two or more kinds of metal oxides. This configuration makes it possible to provide a photoelectric conversion element that has an improved photoelectric conversion property even when held at a high temperature.

The photoelectric conversion element manufacturing method according to the second embodiment may include formation of the electron transport layer by coating the composition according to the first embodiment on the first electrode and by firing.

The photoelectric conversion element manufacturing method according to the second embodiment may include laminating the first electrode, the electron transport layer, the photoelectric conversion layer, the hole transport layer, and the second electrode in this order, or may include laminating the first electrode, the electron transport layer, the photoelectric conversion layer, the hole transport layer, and the second electrode in this order on the substrate. The photoelectric conversion element manufacturing method according to the second embodiment may include formation of the photoelectric conversion layer by coating a raw material solution of the photoelectric conversion layer on the electron transport layer and by firing. Alternatively, the method may include formation of the hole transport layer by coating a raw material solution of the hole transport layer on the photoelectric conversion layer and by firing.

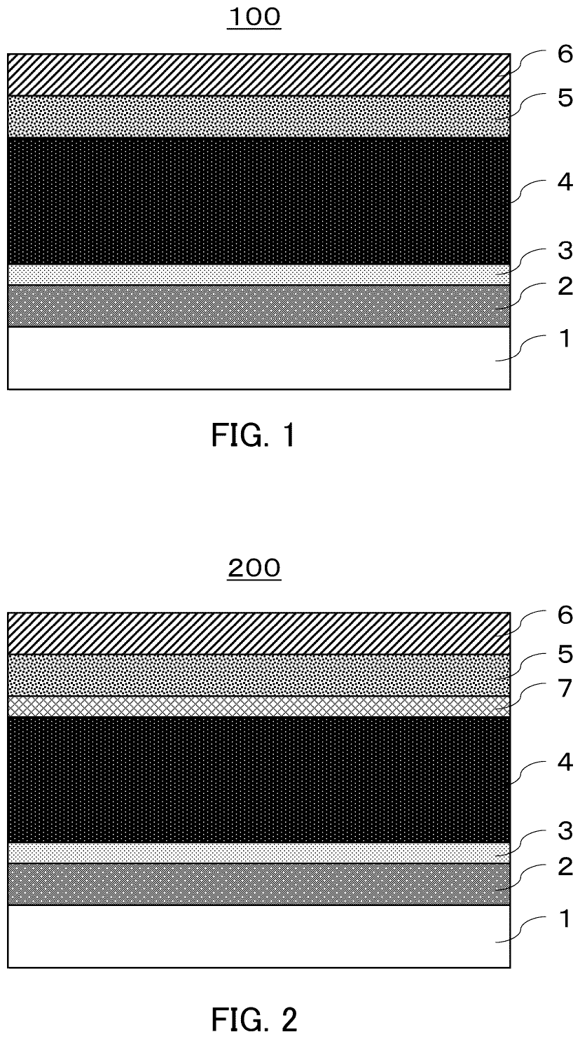

The following explanation is made with reference to FIG. 1 and FIG. 2, with regard to a case where the photoelectric conversion element to be manufactured by the method according to the second embodiment is a solar cell.

FIG. 1 shows a cross-sectional view of a photoelectric conversion element 100 obtainable by the manufacturing method according to the second embodiment.

As shown in FIG. 1, the photoelectric conversion element 100 includes a substrate 1, a first electrode 2, an electron transport layer 3, a photoelectric conversion layer 4, a hole transport layer 5, and a second electrode 6 in this order.

The photoelectric conversion element manufacturing method according to the second embodiment may further include lamination of an intermediate layer on the photoelectric conversion layer. That is, the photoelectric conversion element manufacturing method according to the second embodiment may include laminating the first electrode, the electron transport layer, the photoelectric conversion layer, the intermediate layer, the hole transport layer, and the second electrode in this order. Alternatively, the photoelectric conversion element manufacturing method according to the second embodiment may include formation of the intermediate layer by coating a raw material solution of the intermediate layer on the photoelectric conversion layer and by firing.

This may decrease damage to the solar cell when forming the second electrode (e.g., damage to the hole transport layer), and suppress deterioration of the photoelectric conversion property. The damage to the solar cell when forming the second electrode 6 may include, for example, damage to the hole transport layer, which is caused by plasma, results in a deterioration of properties in a case of forming the second electrode 6 by sputtering, for example.

FIG. 2 shows a cross-sectional view of a photoelectric conversion element 200, which is a variation of the photoelectric conversion element obtainable by the manufacturing method according to the second embodiment.

The photoelectric conversion element 200 includes a substrate 1, a first electrode 2, an electron transport layer 3, a photoelectric conversion layer 4, an intermediate layer 7, a hole transport layer 5, and a second electrode 6 in this order.

The following explanation is made for each component in a case of manufacturing a photoelectric conversion element using the manufacturing method according to the second embodiment.

### (Substrate 1)

A substrate 1 has a function of supporting the layers in the photoelectric conversion element. The substrate 1 can be formed of a transparent material. A glass substrate or a plastic substrate can be used for the material. The plastic substrate may be a plastic film.

In a case where the first electrode 2 is sufficiently strong, the substrate 1 can be omitted since the first electrode 2 is capable of supporting each layer.

### (First Electrode 2)

A first electrode 2 has electrical conductivity.

The first electrode 2 may have a light-transmitting property. For example, the first electrode 2 allows visible to near-infrared light to pass therethrough.

The first electrode 2 may be formed of, for example, a metal oxide being transparent and having electrical conductivity. Examples of the metal oxide include the following:
(i) indium-tin composite oxide,
(ii) indium-zinc composite oxide;
(iii) tin oxide doped with antimony;
(iv) tin oxide doped with fluorine;
(v) zinc oxide doped with at least one element selected from the group consisting of boron, aluminum, gallium, and indium; and
(vi) composites thereof.

The first electrode 2 may be formed using a non-transparent material to have a pattern that allows light to pass therethrough. The pattern that allows light to pass through is, for example, a linear pattern (e.g., a stripe pattern), a wave line pattern, a lattice pattern, (e.g., a mesh pattern) or a perforated-metal-like pattern where a lot of small through holes are regularly or irregularly arranged. When the first electrode 2 has any of these patterns, light can pass through portions without the electrode material.

Examples of the non-transparent electrode material include platinum, gold, silver, copper, aluminum, rhodium, indium, titanium, iron, nickel, tin, zinc, and an alloy including any of these elements. Alternatively, an electrically conductive carbon material can be used as the non-transparent material.

The transmittance of the first electrode 2 may be, for example, 50% or more, or 80% or more. The wavelength of light that is to pass through the first electrode 2 depends on the absorption wavelength of the photoelectric conversion layer 4.

The thickness of the first electrode 2 may be 1 nm or more and 1000 nm or less, for example.

The first electrode 2 can be formed on the surface of the substrate 1, for example, by chemical vapor deposition, sputtering, or the like.

### (Electron Transport Layer 3)

An electron transport layer 3 can be formed by firing the composition according to the first embodiment. For example, the electron transport layer 3 may be formed by coating the composition according to the first embodiment and then by firing. Alternatively for example, the electron transport layer 3 may be formed by coating the composition on the first electrode 2 and then by firing.

The electron transport layer 3 includes a metal oxide. The metal oxide includes a metal oxide included in the composition according to the first embodiment and a metal oxide derived from the metal oxide precursor included in the composition according to the first embodiment. The electron transport layer 3 may include plural kinds of metal oxides. The electron transport layer 3 may include a mixture of plural kinds of metal oxides. The electron transport layer 3 may entirely have a uniform composition.

### (Photoelectric Conversion Layer 4)

A photoelectric conversion layer 4 includes a photoelectric conversion material.

The photoelectric conversion material may be, for example, a perovskite compound. That is, the photoelectric conversion layer 4 may include a perovskite compound.

A perovskite compound has a high light absorption coefficient in the wavelength range of the sunlight spectrum and high carrier mobility. Therefore, a solar cell including such a perovskite compound (namely, perovskite solar cell) has a high photoelectric conversion efficiency.

The perovskite compound can be represented, for example, by a composition formula ABX₃. Here, A is a monovalent cation, B is a metal divalent cation, and X is a monovalent anion.

Examples of the monovalent cation A include an organic cation and an alkali metal cation.

Examples of the organic cation include a methylammonium cation (CH₃NH₃⁺) and a formamidinium cation (NH₂CHNH₂⁺).

Examples of the alkali metal cation include a Cs cation and a Rb cation.

Example of the divalent cation B include a Pb cation, a Sn cation, and a Ge cation.

An example of the monovalent anion X is a halogen anion. The halogen anion is, for example, chlorine, bromine or iodine.

The A, the B, and the X each may include plural kinds of ions.

The thickness of the photoelectric conversion layer 4 may be, for example, 100 nm or more and 2000 nm or less, though it may vary depending on the amount of light absorption.

The photoelectric conversion layer 4 can be formed by coating a solution, for example. The layer may be formed, for example, by coating on the electron transport layer 3.

In a case where the photoelectric conversion element is a light-emitting element, the photoelectric conversion layer may be called also a light-emitting layer.

### (Intermediate Layer 7)

An intermediate layer 7 is, for example, disposed between the photoelectric conversion layer 4 and the hole transport layer 5.

The intermediate layer 7 includes a compound of at least one selected from the group consisting of a chloride, a bromide and an iodide.

The compound included in the intermediate layer 7 may include an ammonium cation.

The compound included in the intermediate layer 7 may include carbon and may have a carbon number of 8 or less. When the carbon number is 8 or less, an increase in the hydrophobicity can be suppressed, and thus, the hole transport layer 5 can be coated more easily and uniformly on the intermediate layer.

The compound included in the intermediate layer 7 may include carbon and have a carbon number of 4 or more and 8 or less. By making the carbon number of the compound 4 or more and 8 or less, the intermediate layer 7 can more effectively decrease, for example, damage of the hole transport layer 5 during formation of the second electrode 6, and can also prevent the increase of hydrophobicity of the intermediate layer 7.

The compound included in the intermediate layer 7 is, for example, represented by the following formula (1).

R—NH₃X . . . (1)
Here, in the formula (1),
R is a hydrocarbon group, and
X is at least one selected from the group consisting of chlorine, bromine, and iodine.

In the formula (1), the R may be a hydrocarbon group having a carbon number of 8 or less. Further, the R may be a hydrocarbon group having a carbon number of 4 or more and 8 or less.

In the formula (1), the R may be an alkyl group, a phenyl group, or a phenylalkyl group.

The compound included in the intermediate layer 7 may be at least one selected from the group consisting of butylammonium bromide, hexylammonium bromide, octylammonium bromide, phenylethylammonium bromide, and phenylethylammonium iodide.

The compound included in the intermediate layer 7 may be butylammonium bromide from the viewpoint of high affinity to photoelectric conversion materials (for example, perovskite compounds) and hole transport materials.

The compound included in the intermediate layer 7 may be phenylethylammonium iodide from the viewpoint of excellent heat resistance.

The intermediate layer 7 may have a thickness of less than 10 nm so as not to impede charge injection.

### (Hole Transport Layer 5)

A hole transport layer 5 includes a hole transport material. The hole transport material is a material that transports holes.

The hole transport material may be a triphenylamine derivative.

Examples of the triphenylamine derivative include

poly[bis(4-phenyl)(2,4,6-triphenylmethyl)amine] (hereinafter, this will be called “PTAA”) and a PTAA derivative. In the PTAA derivative, one or some of hydrogen atoms or methyl groups of the PTAA may be substituted by one or some other functional groups. For example, one or some of methyl group of the PTAA may be substituted by one or some of hydrogen atoms or methoxy groups. Alternatively, one or some of the hydrogen atoms of the PTAA may be substituted by one or some of methyl groups or methoxy groups.

The hole transport layer 5 may include not only the triphenylamine derivative but any other hole transport material. Examples of the hole transport material include an organic substance or an inorganic semiconductor.

Examples of the organic substance to be used as the hole transport material include poly(3-hexylthiophene-2,5-diyl) (hereinafter, this will be canned “P3HT”) and poly(3,4-ethylenedioxythiophene) (hereinafter, this will be called “PEDOT”). The organic substance may be a polymer though its molecular weight is not particularly limited.

Examples of the inorganic semiconductor to be used as the hole transport material include carbon-based materials such as Cu₂O, CuGaO₂, CuSCN, Cul, CuPC, NiOₓ₁, MoOₓ₂, V₂O₅, and a graphene oxide. Here, 0<×1 and 1≤×1≤1.5 may be satisfied. Further, 0<×2 and 2≤×2≤3 may be satisfied.

The hole transport layer 5 may include not only the hole transport layer but a fluoroboron-based compound. The fluoroboron-based compound may be added as an additive to increase hole concentration. The fluoroboron-based compound has high stability and a suitable oxidation-reduction potential for oxidizing a hole transport material.

The fluoroboron-based compound is, for example, a boron compound having a pentafluorophenyl group. Examples of the compound include tris(pentafluorophenyl)borane (TPFPB), 4-Isopropyl-4′-methyldiphenyliodoniumtetrakis(pentafluorophenyl)borate, and N,N-dimethylanilinium tetrakis(pentafluorophenyl)borate.

The fluoroboron-based compound may be TPFPB or a TPFPB derivative.

The hole transport layer 5 may include a plurality of layers formed from different materials.

For decreasing resistance, the thickness of the hole transport layer 5 may be 1 nm or more and 1000 nm or less, or 10 nm or more and 500 nm or less.

Examples of the method for forming the hole transport layer 5 include a coating method and a printing method. Examples of the coating method include doctor blade coating, bar coating, spray coating, dip coating, and spin coating. An example of the printing method is screen printing. The hole transport layer 5 may be formed by compressing or firing a film obtained by mixing a plurality of materials. In a case where the hole transport material is a low-molecular weight organic substance or an inorganic semiconductor, the hole transport layer 5 may be formed by vacuum deposition. In a case where the photoelectric conversion element includes the intermediate layer 7, the hole transport layer 5 may be formed on the intermediate layer 7.

The hole transport layer 5 may include a supporting electrolyte and a solvent. The supporting electrolyte and the solvent have an effect of stabilizing the holes in the hole transport layer 5.

Examples of the supporting electrolyte include ammonium salts and alkali metal salts. Examples of the ammonium salt include tetrabutylammonium perchlorate, tetraethylammonium hexafluorophosphate, imidazolium salts, and pyridinium salts.

Examples of the alkali metal salt include lithium bis(trifluoromethanesulfonyl)imide (Li-TFSI), LiN(SO₂CₙF₂ₙ₊₁)₂, LiPF₆, LiBF₄, LiPF₆, LiBF₄, lithium perchlorate, and potassium boron tetrafluoride.

The solvent included in the hole transport layer 5 may have a high ionic conductivity. The solvent may be an aqueous solvent or an organic solvent. The solvent may be an organic solvent so as to stabilize a solute. Examples of the organic solvent include heterocyclic compounds such as 4-tert-butylpyridine (hereinafter, this will be called “tBP”), pyridine, and N-methylpyrrolidone.

For the solvent, an ionic liquid may be used alone or as a mixture with one or more other kinds of solvents. The ionic liquid has low volatility and high flame retardancy.

Examples of the ionic liquid include imidazolium compounds such as 1-ethyl-3-methylimidazolium tetracyanoborate, pyridine compounds, alicyclic amine compounds, aliphatic amine compounds, and azonium amine compounds.

### (Second Electrode 6)

A second electrode 6 has electrical conductivity.

Of the first electrode 2 and the second electrode 6, at least the electrode on the side through which light enters needs to have a light-transmitting property. As a result, either the first electrode 2 or the second electrode 6 may not be required to have a light-transmitting property. That is, either the first electrode 2 or the second electrode 6 may be free of a material having a light-transmitting property, or may be free of a pattern including an opening portion that transmits light.

The second electrode 6, for example, may be formed of an oxide that is transparent and electrically conductive. Examples of the oxide include an indium-tin composite oxide, an indium-zinc composite oxide, and an indium-tungsten composite oxide. In this way, the second electrode 6 may include an electrically conductive oxide including indium oxide as a base material. From the viewpoint of stability of film quality, the second electrode 6 may include an indium-zinc composite oxide.

An example of the method for forming the second electrode 6 is vapor deposition. Examples of the vapor deposition include chemical vapor deposition and sputtering. The second electrode 6 may be, for example, formed on the hole transport layer 5 by sputtering.

### Other Embodiment

### (Additional Statement)

The above description of the embodiment discloses the following technology.

### (Technique 1)

A composition including:
a metal oxide;
a metal oxide precursor; and
a solvent, wherein
the metal oxide precursor includes at least one selected from the group consisting of a metal acetate, a metal carbonate, a metal hydroxide, a metal alkoxide, and a metal acetylacetonate complex, and
the metal oxide and the metal oxide precursor include different metal elements.

This makes it possible to provide a composition suitable for forming a structure that includes plural kinds of metal oxides and where the metal oxides are uniformly mixed in the structure.

### (Technique 2)

The composition according to Technique 1, wherein the metal oxide includes SnO₂. This makes it possible to provide a composition suitable for forming a structure that includes plural kinds of metal oxides including SnO₂ and where the metal oxides are uniformly mixed in the structure.

### (Technique 3)

The composition according to Technique 1 or 2, wherein the metal oxide precursor includes a metal acetate. This makes it possible to provide a composition further suitable for forming a structure that includes plural kinds of metal oxides and where the metal oxides are uniformly mixed in the structure.

### (Technique 4)

The composition according to Technique 3, wherein the metal acetate includes at least one selected from the group consisting of magnesium acetate, aluminum acetate, and manganese acetate. This makes it possible to provide a composition further suitable for forming a structure that includes plural kinds of metal oxides and where the metal oxides are uniformly mixed in the structure.

### (Technique 5)

The composition according to Technique 4, wherein the metal acetate includes magnesium acetate. This makes it possible to provide a composition further suitable for forming a structure that includes plural kinds of metal oxides and where the metal oxides are uniformly mixed in the structure.

### (Technique 6)

The composition according to any one of Techniques 1 to 5, wherein a molar ratio of the metal oxide precursor to the metal oxide is 0.002 or more and 0.667 or less. This makes it possible to form a structure that may include the metal oxide, and when the metal oxide is regarded as consisting of spherical particles of the same diameter, the metal oxide particles may be in close-packed contact with one another. It also makes it easier for the metal oxide precursor to exhibit its effect. For example, by using such a composition to produce a photoelectric conversion element, it is possible to achieve an improved photoelectric conversion property even in a case where the element is held at a high temperature.

### (Technique 7)

The composition according to Technique 6, wherein the molar ratio is 0.0045 or more and 0.0455 or less. This makes it easier for the metal oxide precursor to exhibit its effect. For example, by using such a composition to produce a photoelectric conversion element, it is possible to achieve an improved photoelectric conversion property even in a case where the element is held at a high temperature.

### (Technique 8)

The composition according to any one of Techniques 1 to 7, wherein the solvent includes water. This makes it possible to provide a composition further suitable for forming a structure that includes plural kinds of metal oxides and where the metal oxides are uniformly mixed in the structure.

### (Technique 9)

The composition according to any one of Techniques 1 to 8, wherein the metal oxide is particulate and has an average particle diameter of 100 nm or less. This makes it possible to provide a structure with low resistance.

### (Technique 10)

A method for manufacturing a photoelectric conversion element, the photoelectric conversion element including: a first electrode; a second electrode; and a metal-oxide-containing layer, wherein the method includes forming the metal-oxide-containing layer by firing the composition according to any one of Techniques 1 to 9. This makes it possible to manufacture a photoelectric conversion element in a simple and easy way, and the photoelectric conversion element may have an improved photoelectric conversion property even in a case where the element is held at a high temperature.

### EXAMPLES

Hereinafter, the present disclosure will be described in more detail with reference to Examples. In each Example, a solar cell was produced as an example of photoelectric conversion element, and the properties were evaluated.

### Example 1

Components of the solar cell according to Example 1 are described below.
Substrate: glass substrate (thickness: 0.7 mm)
First electrode: indium-tin composite oxide (ITO: indium-doped SnO₂ layer, surface resistance: 10 Ω/sq., manufactured by GEOMATEC Co. Ltd.)
Electron transport layer: mixture of tin oxide (SnO₂) and magnesium oxide (MgO) (molar ratio Mg/Sn in a raw material liquid is 0.0045)
Photoelectric conversion layer: a layer mainly including NH₂CHNH₂Pbl₃ (thickness: about 500 nm)
Intermediate layer: phenethylammonium iodide (PEAI manufactured by GreatCell Solar Limited)
Hole transport layer: poly[bis(4-phenyl)(2,4,6-trimethylphenyl)amine] (PTAA manufactured by OKUMOTO Laboratory) (including, as additive, lithium bis(trifluoromethanesulfonyl)imide (Li-TFSI manufactured by Tokyo Chemical Industry Co., Ltd.)) (thickness: about 50 nm)
Second electrode: indium-zinc composite oxide (IZO: 10 wt % ZnO-doped In₂O₃) (thickness: 100 nm)

### (Production of Solar Cell)

For a substrate and first electrode, an electrically conductive glass substrate having an ITO layer formed thereon (manufactured by GEOMATEC Co. Ltd.) was used. The glass substrate was 25 mm square and 0.7 mm thick.

Next, as a raw material liquid for an electron transport layer, the composition of the present disclosure was prepared. Namely, first, 9 mM of aqueous solution (9 mM Mg(CH₃COO)₂·4H₂O aqueous solution) was prepared by dissolving magnesium acetate tetrahydrate (Mg(CH₃COO)₂·4H₂O manufactured by Sigma-Aldrich Co., LLC) in ultrapure water (manufactured by FUJIFILM Wako Pure Chemical Corporation). Subsequently, a SnO₂ colloidal dispersion (15%, manufactured by Alfa Aesar), 9 mM Mg(CH₃COO)₂·4H₂O aqueous solution, and ultrapure water (manufactured by FUJIFILM Wako Pure Chemical Corporation) were mixed in a volume ratio of SnO₂ colloidal dispersion:

Mg(CH₃COO)₂·4H₂O aqueous solution:ultrapure water=2:1:6, thereby preparing a composition as a raw material liquid for an electron transport layer, including SnO₂ and Mg(CH₃COO)₂·4H₂O. The molar ratio of Mg to Sn included in the raw material liquid was 0.0045.

After spin-coating (3000 rpm, 30 seconds) the raw material liquid (500 μL) for an electron transport layer on the first electrode, the coating was annealed on a 150° C. hot plate for 60 minutes. In this way, an electron transport layer was formed.

Next, a solution including Pbl₂ (1.15 M, manufactured by Tokyo Chemical Industry Co., Ltd.), FAI (1.05 M, manufactured by GreatCell Solar Limited), PbBr₂ (0.18 M, manufactured by Tokyo Chemical Industry Co., Ltd.), MABr (0.09 M, manufactured by GreatCell Solar Limited), FABr (0.09 M, manufactured by GreatCell Solar Limited), and MACI (0.42 M, manufactured by GreatCell Solar Limited) was prepared. The solvent of this solution was a mixture of dimethyl sulfoxide (DMSO, manufactured by Acros Organics) and N,N-dimethylformamide (DMF, manufactured by Acros Organics). The mixing ratio of DMSO to DMF in the solution was DMSO:DMF=1:8 by volume. While adding toluene (600 μL) dropwise, this solution (60 μL) was spin-coated (2000 rpm, 55 seconds) onto the electron transport layer. Later, it was annealed on a 150° C. hot plate for 20 seconds, and then, annealed on a 100° C. hot plate for 60 minutes. In this way, a photoelectric conversion layer was formed.

Next, a solution was prepared by dissolving PEAI (2 mM, manufactured by GreatCell Solar Limited) in isopropanol (IPA, manufactured by FUJIFILM Wako Pure Chemical Corporation). This solution (80 μL) was spin-coated (4000 rpm, 20 seconds) on the photoelectric conversion layer, which was then annealed on a 100° C. hot plate for 10 minutes. In this way, an intermediate layer was formed.

Next, a solution was prepared by dissolving PTAA (35 mM, manufactured by OKUMOTO Laboratory) in toluene (manufactured by FUJIFILM Wako Pure Chemical Corporation), and another solution was prepared by dissolving Li-TFSI (1.8 M, manufactured by Tokyo Chemical Industry Co., Ltd.) in acetonitrile (manufactured by FUJIFILM Wako Pure Chemical Corporation). Subsequently, the 35 mM PTAA solution, 4-tert-butylpyridine (tBP, manufactured by Sigma-Aldrich Co., LLC) and the 1.8 M Li-TFSI solution were mixed in a volume ratio of PTAA solution:tBP:Li-TFSI solution=10000:75:72, thereby preparing a raw material liquid for a hole transport layer.

The raw material liquid (80 μL) for a hole transport layer was spin-coated (4000 rpm, 20 seconds) on the intermediate layer, which was then annealed on a 80° C. hot plate for 10 minutes. In this way, a hole transport layer was formed.

Finally, an IZO layer having a thickness of 100 nm was deposited by sputtering on the hole transport layer, by using a 10% ZnO-doped In₂O₃ target under a condition of back pressure: 3×10⁻⁴ Pa, substrate-target distance: 100 mm, substrate temperature: room temperature, power: 20 W, pressure: 1.0 Pa, and oxygen concentration: 0.4%. In this way, a second electrode was formed.

A solar cell according to Example 1 was obtained in the aforementioned way.

The aforementioned steps were conducted in a dry room having a dew point of −40° C. or lower, excepting the step of forming an electron transport layer and a step of forming a second electrode.

### (Evaluation of Solar Cell Properties)

The thus obtained solar cell according to Example 1 was subjected to a thermal endurance test.

First, the initial photoelectric conversion efficiency of the solar cell according to Example 1 was evaluated under simulated sunlight by setting the solar simulator (ALS440B, manufactured by BAS Inc.) to an output of 100 mW/cm². The output current value with respect to the applied voltage was varied from 1.2 V to 0 V and recorded, thereby calculating the photoelectric conversion efficiency. The initial photoelectric conversion efficiency according to Example 1 was 15.8%.

Subsequently, the target solar cell was stored for 300 hours in a constant-temperature chamber of 85° C. After 300 hours, the solar cell was taken out from the constant-temperature chamber and the output of the solar simulator was set to 100 mW/cm² so as to evaluate the photoelectric conversion efficiency under simulated sunlight after the thermal endurance test. The output current value with regard to the applied voltage was varied from 1.2 V to 0 V and recorded, thereby calculating the photoelectric conversion efficiency. The photoelectric conversion efficiency according to Example 1 was 12.8% after the thermal endurance test.

### Example 2

### (Production of Solar Cell)

A solar cell according to Example 2 was obtained in the same manner as Example 1 except that the molar ratio of Mg to Sn included in the composition as the raw material liquid for the electron transport layer was set to 0.0090.

### (Evaluation of Solar Cell Properties)

The photoelectric conversion efficiency of the solar cell according to Example 2 after the thermal endurance test was evaluated in the same manner as Example 1. The initial photoelectric conversion efficiency of the solar cell according to Example 2 was 15.4%, and the photoelectric conversion efficiency after the thermal endurance test was 13.0%.

### Example 3

### (Production of Solar Cell)

A solar cell according to Example 3 was obtained in the same manner as Example 1 except that the molar ratio of Mg to Sn included in the composition as the raw material liquid for the electron transport layer was set to 0.0136.

### (Evaluation of Solar Cell Properties)

The photoelectric conversion efficiency of the solar cell according to Example 3 after the thermal endurance test was evaluated in the same manner as Example 1. The initial photoelectric conversion efficiency of the solar cell according to Example 3 was 15.3%, and the photoelectric conversion efficiency after the thermal endurance test was 13.3%.

### Example 4

### (Production of Solar Cell)

A solar cell according to Example 4 was obtained in the same manner as Example 1 except that the molar ratio of Mg to Sn included in the composition as the raw material liquid for the electron transport layer was set to 0.0182.

(Evaluation of Solar Cell Properties) The photoelectric conversion efficiency of the solar cell according to Example 4 after the thermal endurance test was evaluated in the same manner as Example 1. The initial photoelectric conversion efficiency of the solar cell according to Example 4 was 15.8%, and the photoelectric conversion efficiency after the thermal endurance test was 13.3%.

### Example 5

### (Production of Solar Cell)

A solar cell according to Example 5 was obtained in the same manner as Example 1 except that the molar ratio of Mg to Sn included in the composition as the raw material liquid for the electron transport layer was set to 0.0227.

### (Evaluation of Solar Cell Properties)

The photoelectric conversion efficiency of the solar cell according to Example 5 after the thermal endurance test was evaluated in the same manner as Example 1. The initial photoelectric conversion efficiency of the solar cell according to Example 5 was 15.6%, and the photoelectric conversion efficiency after the thermal endurance test was 14.3%.

### Example 6

### (Production of Solar Cell)

A solar cell according to Example 6 was obtained in the same manner as Example 1 except that the molar ratio of Mg to Sn included in the composition as the raw material liquid for the electron transport layer was set to 0.0273.

### (Evaluation of Solar Cell Properties)

The photoelectric conversion efficiency of the solar cell according to Example 6 after the thermal endurance test was evaluated in the same manner as Example 1. The initial photoelectric conversion efficiency of the solar cell according to Example 6 was 14.5%, and the photoelectric conversion efficiency after the thermal endurance test was 13.8%.

### Example 7

### (Production of Solar Cell)

A solar cell according to Example 7 was obtained in the same manner as Example 1 except that the molar ratio of Mg to Sn included in the composition as the raw material liquid for the electron transport layer was set to 0.0364.

### (Evaluation of Solar Cell Properties)

The photoelectric conversion efficiency of the solar cell according to Example 7 after the thermal endurance test was evaluated in the same manner as Example 1. The initial photoelectric conversion efficiency of the solar cell according to Example 7 was 14.1%, and the photoelectric conversion efficiency after the thermal endurance test was 13.7%.

### Example 8

### (Production of Solar Cell)

A solar cell according to Example 8 was obtained in the same manner as Example 1 except that the molar ratio of Mg to Sn included in the composition as the raw material liquid for the electron transport layer was set to 0.0455.

### (Evaluation of Solar Cell Properties)

The photoelectric conversion efficiency of the solar cell according to Example 8 after the thermal endurance test was evaluated in the same manner as Example 1. The initial photoelectric conversion efficiency of the solar cell according to Example 8 was 13.9%, and the photoelectric conversion efficiency after the thermal endurance test was 13.7%.

### Example 9

### (Production of Solar Cell)

A solar cell according to Example 9 was obtained in the same manner as Example 1 except that the procedure for forming the electron transport layer was modified as described below.

Into 4090 μL of ultrapure water (manufactured by FUJIFILM Wako Pure Chemical Corporation), 17.9 mg of aluminum hydroxide diacetate (aluminum acetate, basic, manufactured by Sigma-Aldrich Co., LLC), which was shaken and filtrated with a membrane filter (manufactured by ADVANTEC CO., LTD.) to recover the filtrate. In this way, an aqueous solution of aluminum acetate was obtained. Subsequently, a SnO₂ colloidal dispersion (15%, manufactured by Alfa Aesar), an aqueous solution of aluminum acetate, and ultrapure water (manufactured by FUJIFILM Wako Pure Chemical Corporation) were mixed in a volume ratio of SnO₂ colloidal dispersion:aluminum acetate aqueous solution:ultrapure water=2:4:3 to prepare a composition as a raw material liquid for an electron transport layer including SnO₂ and an aluminum acetate aqueous solution.

### (Evaluation of Solar Cell Properties)

The photoelectric conversion efficiency of the solar cell according to Example 9 after the thermal endurance test was evaluated in the same manner as Example 1. The initial photoelectric conversion efficiency of the solar cell according to Example 9 was 14.2%, and the photoelectric conversion efficiency after the thermal endurance test was 13.7%.

### Comparative Example 1

### (Production of Solar Cell)

A solar cell according to Comparative Example 1 was obtained in the same manner as Example 1 except that a raw material liquid consisting of SnO₂ and free of Mg was used as the raw material liquid for an electron transport layer, and that the duration of annealing after spin-coating of the raw material liquid for the electron transport layer was set to 30 minutes.

Specifically in Comparative Example 1, a raw material liquid for an electron transport layer was prepared by mixing a SnO₂ colloidal dispersion (15%, manufactured by Alfa Aesar) and ultrapure water (manufactured by FUJIFILM Wako Pure Chemical Corporation) in a volume ratio of SnO₂ colloidal dispersion:ultrapure water=2:7.

### (Evaluation of Solar Cell Properties)

The photoelectric conversion efficiency of the solar cell according to Comparative Example 1 after the thermal endurance test was evaluated in the same manner as Example 1. The initial photoelectric conversion efficiency of the solar cell according to Comparative Example 1 was 15.2%, and the photoelectric conversion efficiency after the thermal endurance test was 10.7%.

### Comparative Example 2

### (Production of Solar Cell)

A solar cell according to Comparative Example 2 was obtained in the same manner as Example 1 except that the procedure of forming an electron transport layer was modified as described below.

A raw material liquid for an electron transport layer, the liquid including SnO₂, was prepared by mixing a SnO₂ colloidal dispersion (15%, manufactured by Alfa Aesar) and ultrapure water (manufactured by FUJIFILM Wako Pure Chemical Corporation) in a volume ratio of SnO₂ colloidal dispersion:ultrapure water=2:7. This raw material liquid (500 μL) was coated by spin-coating (3000 rpm, 30 seconds) on a first electrode, and then annealed for 30 minutes on a 150° C. hot plate, thereby forming a SnO₂ layer. Subsequently, 2 mM of Mg(CH₃COO)₂·4H₂O solution was prepared by dissolving Mg(CH₃COO)₂·4H₂O (manufactured by Sigma-Aldrich Co., LLC) in ethanol (manufactured by FUJIFILM Wako Pure Chemical Corporation). The concentration of the Mg(CH₃COO)₂·4H₂O solution in Comparative Example 2 was substantially the same level as the concentration of the Mg(CH₃COO)₂·4H₂O included in the raw material solution for an electron transport layer used in Example 2. The Mg(CH₃COO)₂·4H₂O solution (150 μL) was spin-coated (3000 rpm, 30 seconds) on the SnO₂ layer and then, annealed for 60 minutes on a 150° C. hot plate. In this way, an electron transport layer was formed.

### (Evaluation of Solar Cell Properties)

The photoelectric conversion efficiency of the solar cell according to Comparative Example 2 after the thermal endurance test was evaluated in the same manner as Example 1. The initial photoelectric conversion efficiency of the solar cell according to Comparative Example 2 was 14.5%, and the photoelectric conversion efficiency after the thermal endurance test was 12.0%.

### Comparative Example 3

### (Production of Solar Cell)

A solar cell according to Comparative Example 3 was obtained in the same manner as Comparative Example 2 except that the concentration of the Mg(CH₃COO)₂·4H₂O solution to be coated on the SnO₂ layer was set to 4 mM. The concentration of the Mg(CH₃COO)₂·4H₂O solution in Comparative Example 3 was substantially the same level as the concentration of the Mg(CH₃COO)₂·4H₂O included in the raw material liquid for an electron transport layer used in Example 4.

### (Evaluation of Solar Cell Properties)

The photoelectric conversion efficiency of the solar cell according to Comparative Example 3 after the thermal endurance test was evaluated in the same manner as Example 1. The initial photoelectric conversion efficiency of the solar cell according to Comparative Example 3 was 13.5%, and the photoelectric conversion efficiency after the thermal endurance test was 10.1%.

### Comparative Example 4

### (Production of Solar Cell)

A solar cell according to Comparative Example 4 was obtained in the same manner as Comparative Example 2 except that the concentration of the Mg(CH₃COO)₂·4H₂O solution to be coated on the SnO₂ layer was set to 6 mM. The concentration of the Mg(CH₃COO)₂·4H₂O solution in Comparative Example 4 was substantially the same level as the concentration of the Mg(CH₃COO)₂·4H₂O included in the raw material liquid for an electron transport layer used in Example 6.

### (Evaluation of Solar Cell Properties)

The photoelectric conversion efficiency of the solar cell according to Comparative Example 4 after the thermal endurance test was evaluated in the same manner as Example 1. The initial photoelectric conversion efficiency of the solar cell according to Comparative Example 4 was 14.2%, and the photoelectric conversion efficiency after the thermal endurance test was 11.4%.

### Comparative Example 5

### (Production of Solar Cell)

A solar cell according to Comparative Example 5 was obtained in the same manner as Comparative Example 2 except that the concentration of the Mg(CH₃COO)₂·4H₂O solution to be coated on the SnO₂ layer was set to 8 mM. The concentration of the Mg(CH₃COO)₂·4H₂O solution in Comparative Example 5 was substantially the same level as the concentration of the Mg(CH₃COO)₂·4H₂O included in the raw material liquid for an electron transport layer used in Example 7.

### (Evaluation of Solar Cell Properties)

The photoelectric conversion efficiency of the solar cell according to Comparative Example 5 after the thermal endurance test was evaluated in the same manner as Example 1. The initial photoelectric conversion efficiency of the solar cell according to Comparative Example 5 was 14.6%, and the photoelectric conversion efficiency after the thermal endurance test was 12.7%.

### Comparative Example 6

### (Production of Solar Cell)

A solar cell according to Comparative Example 6 was obtained in the same manner as Example 1 except that the procedure of forming an electron transport layer was modified as described below.

A raw material liquid for an electron transport layer was prepared by mixing a SnO₂ colloidal dispersion (15%, manufactured by Alfa Aesar) and ultrapure water (manufactured by FUJIFILM Wako Pure Chemical Corporation) in a volume ratio of SnO₂ colloidal dispersion:ultrapure water=2:7. This raw material liquid (500 μL) was coated by spin-coating (3000 rpm, 30 seconds) on a first electrode, and then annealed for 30 minutes on a 150° C. hot plate, thereby forming a SnO₂ layer. Subsequently, 17.7 mg of aluminum hydroxide diacetate (aluminum acetate, basic, manufactured by Sigma-Aldrich Co., LLC) was added to 4045 μL of ethanol (FUJIFILM Wako Pure Chemical Corporation), shaken, and filtered with a membrane filter (CP020-AN manufactured by ADVANTEC CO., LTD.) to recover the filtrate. In this way, an aluminum acetate solution was obtained. The aluminum acetate solution (150 μL) was spin-coated (3000 rpm, 30 seconds) on the SnO₂ layer, and then, annealed on a 150° C. hot plate for 60 minutes. In this way, an electron transport layer was formed.

### (Evaluation of Solar Cell Properties)

The photoelectric conversion efficiency of the solar cell according to Comparative Example 6 after the thermal endurance test was evaluated in the same manner as Example 1. The initial photoelectric conversion efficiency of the solar cell according to Comparative Example 6 was 14.1%, and the photoelectric conversion efficiency after the thermal endurance test was 12.7%.

The “Mg/Sn ratio” shown in Table 1 indicates a molar ratio of magnesium acetate to SnO₂ used for forming an electron transport layer. That is, the “Mg/Sn ratio” in each of Examples 1 to 8 indicates a molar ratio of magnesium acetate to SnO₂ in a composition used for forming an electron transport layer. The “Mg/Sn ratio” in Comparative Examples 1 to 5 indicates a molar ratio of magnesium acetate to SnO₂ used for forming a SnO₂ layer, where the magnesium acetate is used for a solution to be coated on the SnO₂ layer.

TABLE 1

| | Electron | Mg/Sn | Photoelectric conversion |
|---|---|---|---|
| | transport | ratio | efficiency (%) after |
| | layer | (molar ratio) | thermal endurance test |
| Example 1 | Mixture of SnO₂ and MgO | 0.0045 | 12.8 |
| Example 2 | Mixture of SnO₂ and MgO | 0.0090 | 13.0 |
| Example 3 | Mixture of SnO₂ and MgO | 0.0136 | 13.3 |
| Example 4 | Mixture of SnO₂ and MgO | 0.0182 | 13.3 |
| Example 5 | Mixture of SnO₂ and MgO | 0.0227 | 14.3 |
| Example 6 | Mixture of SnO₂ and MgO | 0.0273 | 13.8 |
| Example 7 | Mixture of SnO₂ and MgO | 0.0364 | 13.7 |
| Example 8 | Mixture of SnO₂ and MgO | 0.0455 | 13.7 |
| Comparative | SnO₂ | 0 | 10.7 |
| Example 1 | | | |
| Comparative | SnO₂/MgO laminate | 0.0090 | 12.0 |
| Example 2 | | | |
| Comparative | SnO₂/MgO laminate | 0.0182 | 10.1 |
| Example 3 | | | |
| Comparative | SnO₂/MgO laminate | 0.0273 | 11.4 |
| Example 4 | | | |
| Comparative | SnO₂/MgO laminate | 0.0364 | 12.7 |
| Example 5 | | | |

TABLE 2

| | Electron | Photoelectric conversion |
|---|---|---|
| | transport | efficiency (%) after |
| | layer | thermal endurance test |
| Example 9 | Mixture of SnO₂ and Al₂O₃ | 13.7 |
| Comparative | SnO₂/Al₂O₃ laminate | 12.7 |
| Example 6 | | |

### (Consideration)

The solar cells according to Examples 1 to 8 each has an electron transport layer formed by using a composition including a mixture of SnO₂, magnesium acetate and ultrapure water, while the solar cell according to Comparative Example 1 has an electron transport layer consisting of SnO₂, and the solar cells according to Comparative Examples 2 to 5 each has an electron transport layer as a laminate of a SnO₂ layer and a MgO layer. As shown in Table 1, the solar cells according to Examples 1 to 8 exhibited a higher photoelectric conversion efficiency after storage at 85° C. for 300 hours in comparison with the solar cells of Comparative Examples 1 and 2 to 5.

The solar cells according to Example 9 has an electron transport layer formed by using a composition including a mixture of SnO₂, aluminum acetate and ultrapure water, while the solar cell according to Comparative Example 1 has an electron transport layer consisting of SnO₂, and the solar cell according to Comparative Examples 6 has an electron transport layer as a laminate of a SnO₂ layer and an Al₂O₃ layer. As shown in Table 2, the solar cell according to Example 9 exhibited a higher photoelectric conversion efficiency after storage at 85° C. for 300 hours in comparison with the solar cells of Comparative Examples 1 and 6.

Although the present disclosure of the composition described above is based on the embodiments, the present disclosure is not limited to these embodiments. The applications of the present disclosure compositions are not limited to photoelectric conversion elements, but the compositions can be used in a variety of applications to form a structure including a metal oxide.

### INDUSTRIAL APPLICABILITY

The composition of the present disclosure can be used in a variety of applications to form a structure that includes a metal oxide.

What is claimed is:

1. A composition comprising:
a metal oxide;
a metal oxide precursor; and
a solvent, wherein
the metal oxide precursor includes at least one selected from the group consisting of a metal acetate, a metal carbonate, a metal hydroxide, a metal alkoxide, and a metal acetylacetonate complex, and
the metal oxide and the metal oxide precursor include different metal elements.

2. The composition according to claim 1, wherein
the metal oxide includes SnO₂.

3. The composition according to claim 1, wherein
the metal oxide precursor includes a metal acetate.

4. The composition according to claim 3, wherein
the metal acetate includes at least one selected from the group consisting of magnesium acetate, aluminum acetate, and manganese acetate.

5. The composition according to claim 4, wherein
the metal acetate includes magnesium acetate.

6. The composition according to claim 1, wherein
a molar ratio of the metal oxide precursor to the metal oxide is 0.002 or more and 0.667 or less.

7. The composition according to claim 6, wherein
the molar ratio is 0.0045 or more and 0.0455 or less.

8. The composition according to claim 1, wherein
the solvent includes water.

9. The composition according to claim 1, wherein
the metal oxide is particulate and has an average particle diameter of 100 nm or less.

10. A method for manufacturing a photoelectric conversion element, the photoelectric conversion element comprising: a first electrode; a second electrode; and a metal-oxide-containing layer, wherein
the method includes forming the metal-oxide-containing layer by firing the composition according to claim 1.
